(19) United States
(12) Patent Application Publication
(10) Pub. No.: US 2021/0313207 A1
(43) Pub. Date: Oct. 7, 2021

(54) WAFER IMAGE CAPTURING APPARATUS AND METHOD OF WAFER IMAGE CAPTURING

(71) Applicant: CHENG MEI INSTRUMENT TECHNOLOGY CO., LTD., Zhubei City (TW)

(72) Inventors: Cheng-Tao TSAI, Zhubei City (TW); Chao-Yu HUANG, Zhubei City (TW); Te-Chun CHEN, Zhubei City (TW); Cheng-Yang HSIEH, Zhubei City (TW)

(21) Appl. No.: 17/218,249

(22) Filed: Mar. 31, 2021

Related U.S. Application Data
(60) Provisional application No. 63/003,320, filed on Apr. 1, 2020.

(51) Int. Cl. H01L 21/67; H04N 5/247; H04N 5/265; H01L 21/677; H01L 21/687

(52) U.S. Cl. CPC H01L 21/67265; H04N 5/247; H01L 21/68707; H01L 21/67766; H01L 21/67778; H04N 5/265

(57) ABSTRACT

A wafer image capturing apparatus, including a loud/unload system, at least one imaging station and a conveying device, are provided. The loud/unload system contains a plurality of wafers. The at least one imaging includes a platform and an image capturing device. The conveying device includes a movable component for moving the wafer to a platform of at least one imaging station. An image capturing device is configured to capture an image of the wafer. A method for image capturing is also provided, including: operating a conveying device to pick a wafer from a load/unload system and move the wafer to at least one imaging station; and operating at least one image capturing device to capture an image from above or below the imaging station. Thus, the flexibility and efficiency of wafer image capturing can be improved.

### CROSS-REFERENCES TO RELATED APPLICATIONS

This application claims priority to U.S. Provisional Patent Application No. 63/003,320, filed on Apr. 1, 2020, the disclosure of which is incorporated by reference herein in its entirety.

### BACKGROUND OF THE INVENTION

### Field of the Invention

The present invention relates to a wafer image capturing apparatus and a wafer image capturing method thereof.

### Descriptions of the Related Art

In the past, wafer processing was only performed on a single side (front or back) of the wafer. Therefore, the image capturing and inspection, as provided in the process requirements, are only performed on the single side.

With the development of technology, wafer processing will no longer be limited to single-sided, but there will also be a need to perform processing on both sides (front and back) of the wafer. Therefore, it is necessary to capture images on both sides for subsequent processes.

However, to capture images of both sides of the wafer by operating the same machine, the overall capturing speed will be limited by the capturing speed on one of the two sides, the quantity of images and data that can be produced per hour is limited due to the size of the wafer to be tested, and therefore, on the whole, the image capture process is slow, inefficient, and increases time costs.

Accordingly, a need exists in the art to improve the aforesaid drawbacks.

### SUMMARY OF THE INVENTION

An objective of the present invention is to provide a wafer image capturing apparatus and a method of wafer image capturing thereof. The wafer image capturing apparatus comprises at least one imaging station for flexibly selecting the forms of image capturing according to different inspection requirements and not affecting the capturing efficiency.

To achieve the above objective, the wafer image capturing apparatus according to the present invention comprises: a load/unload system comprising a containment area for containing a plurality of wafers; at least one imaging station disposed on a side of the load/unload system and comprising a carrier and an image capturing device, wherein the image capturing device is disposed above or below the carrier; and a conveying device disposed between the load/unload system and the at least one imaging station and comprising a movable component for placing one of the plurality of wafers onto the carrier of the at least one imaging station, wherein, the image capturing device is configured to capture an image of the one of the plurality of wafers.

To achieve the above objective, the method of wafer image capturing according to the present invention comprises: operating a conveying device to pick a wafer from a load/unload system and moving the wafer onto at least one imaging station; and operating at least one image capturing device to capture an image of the wafer from above or below the at least one imaging station.

In one embodiment, the conveying device comprises a mechanical arm, which is configured to move horizontally, vertically and rotatably between the loading/unloading system and the at least one imaging station.

In one embodiment, the carrier is configured to horizontally and rotatably, secure and support the one of the plurality of wafers.

In one embodiment, at least one imaging station comprises a first imaging station, which comprises a first carrier and a first image capturing device, wherein the first image capturing device is disposed below the first carrier; and a second imaging station, which comprises a second carrier and a second image capturing device, wherein the second image capturing device is disposed above the second carrier.

In one embodiment, the first imaging station further comprises another first image capturing device, and the two first image capturing devices are disposed above and below the first carrier respectively.

In one embodiment, the second imaging station further comprises another second image capturing device, and the two second image capturing devices are disposed above and below the second carrier respectively.

In one embodiment, in the method of wafer image capturing of the present invention, the step of moving the wafer onto the at least one imaging station further comprises: moving the wafer to a first imaging station and moving the wafer from the first imaging station onto a second imaging station.

In one embodiment, the method of wafer image capturing of the present invention further comprises: after moving the wafer onto the second imaging station, moving another wafer from the load/unload system onto the first imaging station.

In one embodiment, in the method of wafer image capturing of the present invention, the step of operating the at least one image capturing device to capture the image of the wafer further comprises: operating an image capturing device to capture an image of the wafer from above the first imaging station, and operating another image capturing device to capture an image of the wafer from below the second imaging station.

In one embodiment, the method of wafer image capturing of the present invention further comprises: operating two image capturing devices to capture images from above and below the first imaging station; and operating other two image capturing devices to capture images from above and below the second imaging station simultaneously.

In one embodiment, the method of wafer image capturing of the present invention further comprises: combining a plurality of images to obtain a composite image.

In order to make the above objectives, technical features and advantages more obvious and understandable, the following is a detailed description of the preferred embodiments with the accompanying drawings.

### BRIEF DESCRIPTION OF THE DRAWINGS

FIG. 1A is a top schematic view of the wafer image capturing apparatus according to a first preferred embodiment of the present invention;

FIG. 1B is a schematic view of the wafer image capturing apparatus according to the first preferred embodiment of the present invention connected with a processor.

FIG. 2 is a side schematic view of an imaging station of the wafer image capturing apparatus according to the first preferred embodiment of the present invention;

FIG. 3 is a side schematic view of another imaging station of the wafer image capturing apparatus according to the first preferred embodiment of the present invention; and

FIG. 4 is a side schematic view of an imaging station of the wafer image capturing apparatus according to a second preferred embodiment of the present invention.

### DESCRIPTION OF THE PREFERRED EMBODIMENT

The specific embodiments according to the present invention will be described specifically hereinafter. However, without departing from the spirit of the present invention, the present invention may be implemented with various different forms of embodiments, and the scope of the protection of the present invention should not be construed as being limited to what is described in the specification.

Unless clearly indicated otherwise in the context, the singular forms “a”, “the” and similar terms used herein are intended to include the plural forms as well. And the terms “first” and “second” used herein are to describe various elements or components instead of indicating the sequence or priority of these elements or components. In addition, the orientations described herein (such as front, back, above, below, left, right, horizontal, vertical, etc.) are relative orientations, which can be defined according to the arrangement and the operation state of the wafer image capturing apparatus, and are not intended to indicate or imply that the wafer image capturing apparatus and/or wafer movement need to be operated in a specific orientation, and the orientation terms do not deviate from the scope claimed in the present invention within a certain error range, nor can it be interpreted as a limitation to the present invention.

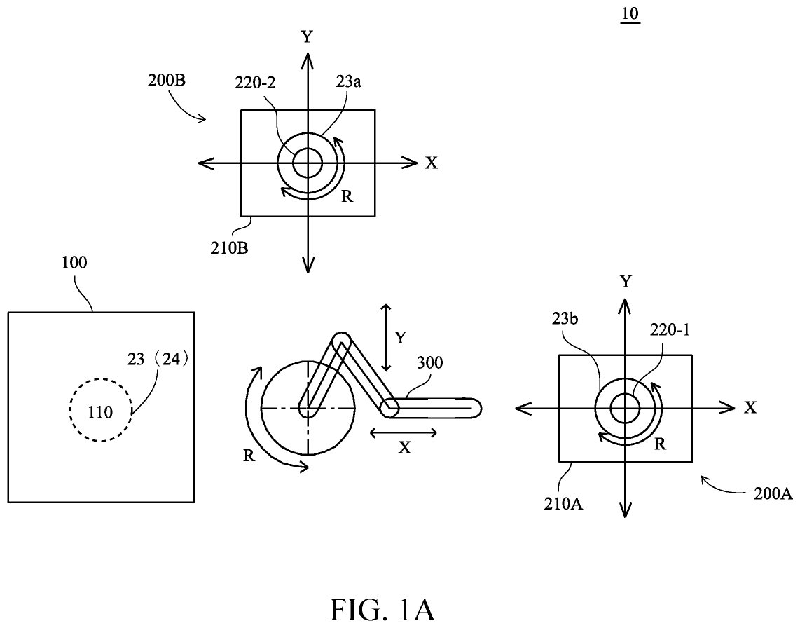

Please refer to FIG. 1A and FIG. 1B, the wafer image capturing apparatus 10 of the present invention may be connected with an external processor 20 to perform a capture of an image of the front and/or the back of a wafer and for subsequent processes including wafer quality management, analysis or cutting. The wafer sizes applicable for the wafer image capturing apparatus 10 are not limited, which means wafers with various sizes may be contained in one wafer image capturing apparatus. Wafer image capturing apparatus 10 comprises a load/unload system 100, at least one imaging station 200 and a conveying device 300. The contents of each element will be explained in detail as follows.

The load/unload system 100 may comprise at least one containment area 110 configured to contain wafers, such as a wafer 23, of which, an image will be captured, and a wafer 24, an image thereof already been captured. The wafer 23 and the wafer 24 may be placed in the same containment area 110, that is, in the same horizontal plane position (XY plane), but in different vertical plane positions (Z plane), so as to reduce the equipment volume and save horizontal movement time. Alternatively, the wafer 23 is located in one containment area 110 (loading area), and the wafer 24 is located in another containment area 110 (unloading area) to avoid possible errors of loading/unloading (not shown).

The at least one imaging station 200 is disposed on a side of the load/unload system 100, and the at least one imaging station 200 comprises a carrier 210 and an image capturing device 220. The carrier 210 may comprise a circular supporting structure 211 which is corresponding to the size of the wafer under test, and the circular supporting structure 211 may be connected with a multi-axial mechanism (not shown) so that the circular supporting structure 211 may move forward, backward, left and right along the horizontal plane (XY plane) and may further rotate clockwise or counterclockwise in the R direction with the vertical axis as the axis to actively and smoothly receive, secure and support the wafer 23. The wafer 23 may be arranged to have a carrier frame, such as a rectangular or circular expander ring, and/or dicing tape, such as blue tape, to make the procedure of moving and securing more stable and avoid the wafer 23 being scattered during subsequent processes.

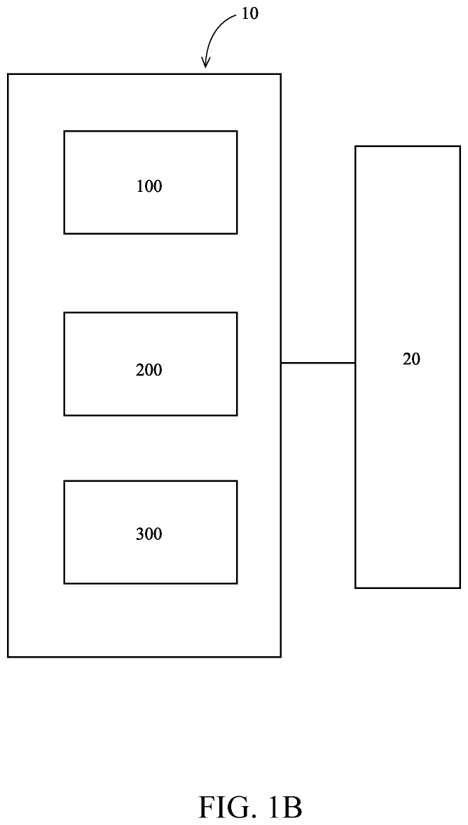

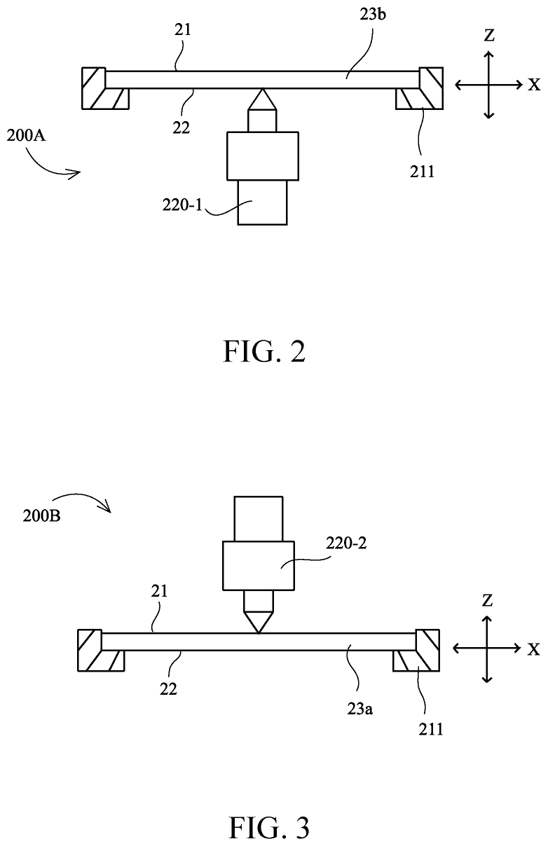

In detail, please continue referring to FIG. 2 and FIG. 3, in the first preferred embodiment, the wafer image capturing apparatus 10 includes two imaging stations 200A, 200B (referred to as Station A and Station B hereinafter). Station A has a carrier 210A and an image capturing device 220-1, wherein the carrier 210A comprises a circular supporting structure 211 for supporting the annular periphery of the wafer 23. The image capturing device 220-1 is disposed below the carrier 210A and is configured to directly face the back side 22 of the wafer 23 to capture an image of the back side 22 when the wafer 23 is placed on the carrier 210A. Station B has a carrier 210B and an image capturing device 220-2, wherein the carrier 210B also comprises a circular supporting structure 211 for supporting the annular periphery of the wafer 23, and the image capturing device 220-2 is disposed above the carrier 210B and is configured to directly face the front side 21 of the wafer 23 to capture an image of the front side 21. The image capturing device 220-1 and the image capturing device 220-2 may adopt different magnifications respectively to capture images; for example, the image capturing device 220-1 may adopt 0.5×, 1.0× or 1.5× magnification, while the image capturing device 220-2 adopts 0.9× magnification. Because the image capturing can be performed separately, the inspection speed will not be effected by the capturing magnification requirement for either side, the sizes of the wafers and the like, and thus the efficiency of inspection may be improved.

Please refer to FIG. 1A again, the conveying device 300 is disposed between the load/unload system 100 and the at least one image station 200 and may comprise a wafer clamp or a vacuum chuck for clamping or sucking one of the plurality of the wafers 23 and placing the wafer 23 onto the carrier 210 of at least one imaging station 200. The conveying device 300 may further comprise a movable component, such as a mechanical arm, having a plurality of connecting shafts, so that the conveying device 300 may move forward, backward, left and right along the horizontal plane (XY plane), move up and down along the vertical plane (Z plane), and further rotate clockwise or counterclockwise in the R direction with the vertical axis as the axis. Accordingly, the wafer 23 may be taken out from the load/unload system 100, moved to the loading range of station A or station B, and then placed stably on the carrier 210A and the carrier 210B.

The above are the technical contents according to wafer image capturing apparatus of the first preferred embodiment of the present invention. Next, the method of wafer image capturing according to the first preferred embodiment of the present invention will be described. The method of wafer image capturing may be implanted by the wafer image capturing apparatus described above (or another wafer image capturing apparatus having substantially the same technical contents), and therefore, the technical contents of the method and the technical contents of the wafer image capturing apparatus can refer to each other, and the repetitive parts will be omitted or simplified.

The method of wafer image capturing may be performed by a processor 20, and the processor 20 may adjust the steps of the method of wafer image capturing according to the process requirements. The method of wafer image capturing is described in detail below with the wafer image capturing apparatus 10 as an example Firstly, operating a conveying device 300 to pick a wafer 23 from a load/unload system 100, and moving the wafer 23 onto at least one image station 200; then operating at least one image capturing device 220 to capture an image of the wafer 23 from above or below the image station 200.

In detail, please refer to FIG. 1A again, the load/unload system 100 may include the wafer 23 for which an image is to be captured or the wafer 24 for which an image has already been captured. The conveying device 300 may move to the range of the load/unload system 100, pick up a wafer 23a from above or to the side of the wafer 23a, and deliver the wafer 23a onto the carrier 210A of station A; then, the image capturing device 220-1 may start to capture an image of the back side 22 of the wafer 23a from below the carrier 210A. After finishing capturing the image of the back side 22, the conveying device 300 then picks up the wafer 23a from the carrier 210A and delivers the wafer 23a onto the carrier 210B of station B; the image capturing device 220-2 starts to capture an image of the front side 21 of the wafer 23a from above the carrier 210B, in the meantime, the conveying device 300 may go back to the load/unload system 100 to pick up a wafer 23b and deliver the wafer 23b onto the carrier 210A of station A to start to capture an image of the back side 22 of the wafer 23b. When the image of the front side 21 of the wafer 23a has been captured and the image of the back side 22 of the wafer 23b has not yet been captured, the conveying device 300 may pick and deliver the wafer 23a back to the load/unload system 100 from the carrier 210B to finish the image capturing of the wafer 23a. The above procedures may be applied repeatedly with the next wafer to be image captured.

In this way, the image capturing device 220-1 and the image capturing device 220-2 may capture the image from above or below the wafer respectively and individually, or the image capturing device 220-1 and the image capturing device 220-2 may capture the images at the same time. Thus, even if the image capturing device 220-1 and the image capturing device 220-2 are configured to have different image capture magnifications, or the sizes of the wafers to be tested are different, the inspection speed and the efficiency may be improved.

The plurality of the inspection data obtained by the image capturing device 220-1 and the image capturing device 220-2 may be transferred to the processor 20 and be analyzed separately; for example, the analysis may comprise defect inspection, code reading and/or wafer alignment, etc. The plurality of the inspection data may be combined into a composite image of a wafer to provide more comprehensive data on subsequent processes.

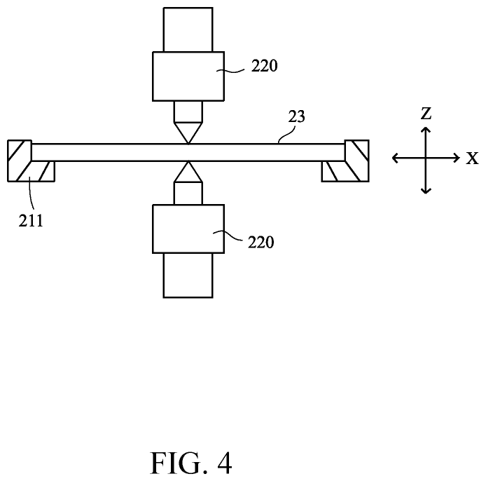

In addition to the arrangement of the first preferred embodiment, as shown in FIG. 4, in the second preferred embodiment, the plurality of imaging stations 200 of the wafer image capturing apparatus 10 and the method of wafer image capturing may further comprise a plurality of image capturing devices 220. The plurality of image capturing devices 220 are disposed above and below the carrier 210 respectively and individually, so that the imaging station 200 may be operated respectively or together depending on the user's requirements. Alternatively, the wafer image capturing apparatus 10 and the method of wafer image capturing may comprise more imaging stations to improve the inspection efficiency. The imaging stations may further become a substitute for imaging stations being maintained or that have malfunctioned.

With the arrangement described above, the apparatus and method of the present invention may select the form of image capturing according to different wafer processes without affecting the overall inspection speed and improve the flexibility and efficiency of the wafer image capturing and inspection.

The above embodiments are merely for introducing the specific embodiments of the present invention to describe the technical features of the invention, the scope of protection of the present disclosure is not limited thereto. Any modifications or equality arrangements that people skilled in this field can apply shall be covered by the scope of protection of the present invention. The protection scope of the present invention shall be subject to the protection scope of the claims.

What is claimed is:

1. A wafer image capturing apparatus, comprising:
a load/unload system comprising a containment area for containing a plurality of wafers;
at least one imaging station disposed on a side of the load/unload system and comprising a carrier and an image capturing device, wherein the image capturing device is disposed above or below the carrier; and
a conveying device disposed between the load/unload system and the at least one imaging station and comprising a movable component for placing one of the plurality of wafers onto the carrier of the at least one imaging station;
wherein, the image capturing device is configured to capture an image of the one of the plurality of wafers.

2. The wafer image capturing apparatus of claim 1, wherein the movable component comprises a mechanical arm configured to move horizontally, vertically and rotatably between the load/unload system and the at least one imaging station.

3. The wafer image capturing apparatus of claim 1, wherein the carrier is configured to horizontally and rotatably secure and support the one of the plurality of wafers.

4. The wafer image capturing apparatus of claim 1, wherein the at least one imaging station comprises:
a first imaging station comprising a first carrier and a first image capturing device, wherein the first image capturing device is disposed below the first carrier; and
a second imaging station, comprising a second carrier and a second image capturing device, wherein the second image capturing device is disposed above the second carrier.

5. The wafer image capturing apparatus of claim 4, wherein the first imaging station further comprises another first image capturing device, and the first image capturing devices are disposed above and below the first carrier respectively.

6. The wafer image capturing apparatus of claim 4, wherein the second imaging station further comprises another second image capturing device, and the second image capturing devices are disposed above and below the second carrier respectively.

7. A method of wafer image capturing, comprising:
operating a conveying device to pick a wafer from a load/unload system and moving the wafer onto at least one imaging station; and
operating at least one image capturing device to capture an image of the wafer from above or below the at least one imaging station.

8. The method of claim 7, wherein the step of moving the wafer onto the at least one imaging station further comprises: moving the wafer to a first imaging station and moving the wafer from the first imaging station onto a second imaging station.

9. The method of claim 8, further comprising: after moving the wafer onto the second imaging station, moving another wafer from the load/unload system onto the first imaging station.

10. The method of claim 8, wherein the step of operating the at least one image capturing device to capture the image of the wafer further comprises: operating an image capturing device to capture an image of the wafer from below the first imaging station, and operating another image capturing device to capture an image of the wafer from above the second imaging station.

11. The method of claim 8, wherein the step of operating the at least one image capturing device to capture the image of the wafer further comprises: operating two image capturing devices to capture images from above and below the first imaging station; and operating another two image capturing devices to capture images from above and below the second imaging station simultaneously.

12. The method of claim 10, further comprising: combining a plurality of images to obtain a composite image.
